(19) United States
(12) Patent Application Publication
(10) Pub. No.: US 2019/0088899 A1
(43) Pub. Date: Mar. 21, 2019

(54) ORGANIC LIGHT EMITTING DIODE DEVICE AND METHOD FOR MANUFACTURING LIQUID MATERIAL TO BE SPRAYED FOR THE DEVICE

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventor: Yunan ZHANG, Shenzhen Guandong (CN)

(21) Appl. No.: 15/576,860

(22) PCT Filed: Nov. 9, 2017
(86) PCT No.: PCT/CN2017/110199

§ 371 Date: Nov. 27, 2017

(30) Foreign Application Priority Data
Sep. 18, 2017 (CN) 201710839371.2

(51) Int. Cl. H01L 51/52; H01L 27/32; H01L 51/50; H01L 51/00; H01L 51/56

(52) U.S. Cl. CPC H01L 51/5234; H01L 27/3246; H01L 51/5215; H01L 51/5012; H01L 51/5056; H01L 2251/558; H01L 51/0005; H01L 51/0021; H01L 51/0022; H01L 51/56; H01L 2251/5315; H01L 51/5072

(57) ABSTRACT

An organic light emitting diode (OLED) device and a method for manufacturing a liquid material to be sprayed for the OLED device are provided. The OLED device includes a substrate, and a pixel defining layer, an anode layer, a hole transport layer, a light emitting layer, an electron transport layer and a cathode layer are laminated on the substrate. The cathode layer is a carbon nanotube-polymer layered composite transparent electrode.

### FIELD OF INVENTION

This disclosure relates to display technology, and more particularly to an organic light emitting diode (OLED) device and a method for manufacturing a liquid material to be sprayed for the OLED device.

### BACKGROUND OF INVENTION

With small displays, mature passive driving technology, large displays, active driving technology has become a mainstream of organic light-emitting research. It uses TFT-driven technology to achieve large-size displays. However, conventional bottom-emitting OLEDs (BOLEDs) use an indium tin oxide (ITO) anode of a transparent substrate as a light-emitting surface. When a non-transparent silicon substrate or amorphous silicon with a small mobility, or an organic TFT is used as a substrate, it easily leads to low light transmittance issues. Therefore, in order to provide large-sized organic light-emitting display panels that are actively driven and have a high brightness, it is necessary to develop top-emitting OLEDs (TOLEDs). By separating a light emitting surface from a substrate (TFT), issues of low light transmittance issues has been fundamentally solved.

In conventional manufacturing process of the top-emitting OLED, a total reflection anode and a structure of a translucent cathode is generally prepared to realize a top-emission of a OLED device, and a microcavity effect of the TOLED is effectively adjusted through structural optimization. However, in such a device structure, in order to ensure translucence of a cathode, it is generally required that a thickness of the cathode is about dozens of nanometers. That will place high demands on conductivity properties of the cathode.

Thus, in a conventional top-emitting OLED device, the conductivity properties of the cathode cannot achieve requirements of a top-emitting device for the transparent cathode, but also cannot achieve requirements of a jet printing process.

### SUMMARY OF INVENTION

The disclosure provides an organic light emitting diode (OLED) device and a method for manufacturing a liquid material to be sprayed for the OLED device for achieving the requirements of the top-emitting device for the transparent cathode, and further for achieving the requirements of the jet printing process.

In order to solve the above drawbacks, a technical solution provided by the disclosure is as follows.

This disclosure provides an organic light emitting diode (OLED) device , which comprises:

a substrate;

a pixel defining layer disposed on the substrate, the pixel defining layer comprising spacer columns spaced from each other for separating two adjacent pixels;

an anode layer disposed on the substrate and located between two adjacent spacer columns;

a hole transport layer disposed on the anode layer;

a light emitting layer disposed on the hole transport layer;

an electron transport layer disposed on the light emitting layer; and

a cathode layer disposed on the electron transport layer;

the cathode layer is a carbon nanotube-polymer layered composite transparent electrode, the cathode layer comprises a carbon nanotube powder and a polymer material, the carbon nanotube powder is selected from the group consisting of single-walled carbon nanotubes, double-walled carbon nanotubes, multi-walled carbon nanotubes and modified carbon nanotubes, the polymer material is an aqueous solution of poly-3,4-ethylenedioxythiophene: polystyrene sulfonate, and a solid content of the aqueous solution is 1.0% to 1.7%.

According to a preferred embodiment of the disclosure, the anode layer is made of indium tin oxide and silver, and wherein a film of the indium tin oxide is made by magnetron sputtering deposition, and a film thickness of the indium tin oxide is between 20 nm and 200 nm; and a film of the silver is made by vacuum deposition, and a thickness of the silver is between 10 nm and 100 nm.

According to a preferred embodiment of the disclosure, the hole transport layer is made of poly 3,4-ethylenedioxythiophene: polystyrene sulfonate, the hole transport layer is formed by a jet printing method, and a film thickness of the hole transport layer is between 1 nm and 100 nm.

According to a preferred embodiment of the disclosure, the light emitting layer is made of a blue luminescent polymer material, the light emitting layer is formed by a jet printing method, and a film thickness of the light emitting layer is between 1 nm and 100 nm.

According to a preferred embodiment of the disclosure, the electron transport layer is made of zinc oxide, the electron transport layer is formed by a jet printing method, and a film thickness of the electron transport layer is between 0.5 nm and 10 nm.

According to a preferred embodiment of the disclosure, the cathode layer is made of carbon nanotubes/(poly 3,4-ethylenedioxythiophene: polystyrene sulfonate), the cathode layer is formed by a jet printing method, and a film thickness of the cathode layer is between 10 nm and 1000 nm.

This disclosure further provides a method for manufacturing a liquid material to be sprayed for the OLED device, which comprises:

a step S1 of directly mixing a carbon nanotube solution with a aqueous solution of poly (3,4-ethylenedioxythiophene): polystyrene sulfonate, and stirring to obtain an uniformly dispersed mixed aqueous solution;

a step S2 of adding a high boiling point solvent having a boiling point greater than 200° C. into the mixed aqueous solution, to reduce a saturated vapor pressure of the mixed aqueous solution, wherein the high boiling solvent is an ether or ester compound;

a step S3 of adding a surface tension adjusting agent into the mixed aqueous solution, wherein small molecule compounds of the surface tension adjusting agent is at least one selected from the group consisting of imidazole and its derivatives, phenol and hydroquinone; and

a step S4 of adding a viscosity modifier into the mixed aqueous solution, wherein the viscosity modifier is at least one selected from the group consisting of alcohols, ethers, esters, phenols and amines.

According to a preferred embodiment of the disclosure, before the step S1, the method further comprises: a step S5 of dispersing the carbon nanotube powder in an aqueous solution of alkylated quaternary ammonium base, then adding a water-soluble anionic surfactant thereinto, and stirring simultaneously, wherein the aqueous solution of alkylated quaternary ammonium base is an organic base aqueous solution of hexadecyltrimethylammonium hydroxide, dodecyltrimethylammonium hydroxide, tetradecyltrimethylammonium hydroxide, or benzyl trimethyl ammonium hydroxide; the water-soluble anionic surfactant is an acid aqueous solution of butylbenzoic, phthalic acid, cinnamic acid, phenylacetic acid, or salicylic acid.

According to a preferred embodiment of the disclosure, before the step S5, the method further comprises: a step S6 of dispersing the carbon nanotube in an organic solvent to obtain a suspension, standing the suspension, centrifuging, washing, and then adding into a concentrated nitric acid to react at 120° C. for 4 h, followed by centrifuging, washing to be neutral, and finally drying to obtain a pure carbon nanotube powder.

This disclosure further provides an organic light emitting diode (OLED) device, which comprises:

a substrate;

a pixel defining layer disposed on the substrate, the pixel defining layer comprising spacer columns spaced from each other for separating two adjacent pixels;

an anode layer disposed on the substrate and located between two adjacent spacer columns;

a hole transport layer disposed on the anode layer;

a light emitting layer disposed on the hole transport layer;

an electron transport layer disposed on the light emitting layer, and

a cathode layer disposed on the electron transport layer;

the cathode layer is a carbon nanotube-polymer layered composite transparent electrode.

According to a preferred embodiment of the disclosure, the anode layer is made of indium tin oxide and silver, and wherein a film of the indium tin oxide is made by magnetron sputtering deposition, and a film thickness of the indium tin oxide is between 20 nm and 200 nm; and a film of the silver is made by vacuum deposition, and a thickness of the silver is between 10 nm and 100 nm.

According to a preferred embodiment of the disclosure, the hole transport layer is made of poly 3,4-ethylenedioxythiophene: polystyrene sulfonate, the hole transport layer is formed by a jet printing method, and a film thickness of the hole transport layer is between 1 nm and 100 nm.

According to a preferred embodiment of the disclosure, the light emitting layer is made of a blue luminescent polymer material, the light emitting layer is formed by a jet printing method, and a film thickness of the light emitting layer is between 1 nm and 100 nm.

According to a preferred embodiment of the disclosure, the electron transport layer is made of zinc oxide, the electron transport layer is formed by a jet printing method, and a film thickness of the electron transport layer is between 0.5 nm and 10 nm

According to a preferred embodiment of the disclosure, the cathode layer is made of carbon nanotubes/(poly 3,4-ethylenedioxythiophene: polystyrene sulfonate), the cathode layer is formed by a jet printing method, and a film thickness of the cathode layer is between 10 nm and 1000 nm.

Advantageous effects of the disclosure are as follows. Compared to conventional top-emitting OLED devices, a carbon nanotube-polymer composite transparent electrode was used as the cathode to enhance a conductivity of a transparent cathode in this disclosure. Besides, excellent optoelectronic properties of carbon nanotubes can achieve the requirements for the transparent cathode of the top-emitting device. Moreover, conductive polymer materials improve a processability of a whole system, and makes the carbon nanotube-polymer layered composite to meet jet printing process requirements.

### DESCRIPTION OF DRAWINGS

In order to more clearly describe the embodiments of this disclosure or the conventional technical solutions, the description is used to make a simple introduction of the drawings used in the following embodiments. The following description of the drawings are merely some embodiments of this disclosure, those of ordinary skill in the art can also obtain other drawings based on these drawings without creative effort.

FIG. 1 is a structural schematic view of an organic light emitting diode (OLED) device according to this disclosure.

FIG. 2 is a flowchart of method for manufacturing a liquid material to be sprayed for the OLED device according to this disclosure.

### DETAILED DESCRIPTION OF PREFERRED EMBODIMENTS

This description of the exemplary embodiments is intended to be read in connection with the accompanying drawings, which are to be considered part of the entire written description. In the description, terms such as “lower”, “upper”, “horizontal”, “vertical”, “above”, “below”, “up”, “down”, “top”, and “bottom”, as well as derivatives thereof, should be construed to refer to the orientation as then described or as shown in the drawing under discussion. These terms are for convenience of description and do not require that the apparatus be constructed or operated in a particular orientation, and do not limit the scope of the disclosure. Referring to the drawings of the disclosure, similar components are labeled with the same number.

The disclosure improves a conventional top-emitting OLED device. In the conventional top-emitting OLED device, a conductive property of a cathode cannot meet requirements for a transparent cathode of the top-emitting OLED device and cannot to meet jet printing process requirements. The disclosure can solve the aforementioned drawbacks.

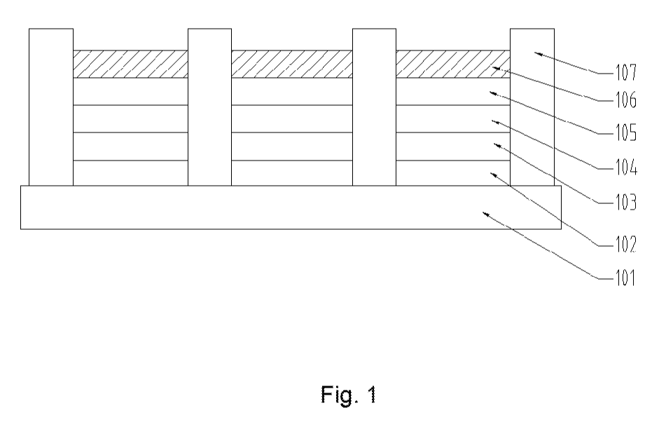

Referring to FIG. 1, a structural schematic view of an organic light emitting diode (OLED) device according to this disclosure is shown. As shown in FIG. 1, the organic light emitting diode (OLED) device comprises: a substrate 101; a pixel defining layer disposed on the substrate 101, the pixel defining layer comprising spacer columns 107 spaced from each other for separating two adjacent pixels; an anode layer 102 disposed on the substrate 101 and located between two adjacent spacer columns 107; a hole transport layer 103 disposed on the anode layer 102; a light emitting layer 104 disposed on the hole transport layer 103; an electron transport layer 105 disposed on the light emitting layer 104; and a cathode layer 106 disposed on the electron transport layer 105. The cathode layer 106 is a carbon nanotube-polymer layered composite transparent electrode.

The cathode layer 106 comprises a carbon nanotube powder and a polymer material, the carbon nanotube powder is selected from the group consisting of single-walled carbon nanotubes, double-walled carbon nanotubes, multi-walled carbon nanotubes and modified carbon nanotubes, the polymer material is an aqueous solution of poly-3,4-ethylenedioxythiophene: polystyrene sulfonate, and a solid content of the aqueous solution is 1.0% to 1.7%. The anode layer 102 is made of indium tin oxide and silver. A film of the indium tin oxide is made by magnetron sputtering deposition, and a film thickness of the indium tin oxide is between 20 nm and 200 nm. A film of the silver is made by vacuum deposition, and a thickness of the silver is between 10 nm and 100 nm. The hole transport layer 103 is made of poly 3,4-ethylenedioxythiophene: polystyrene sulfonate. The hole transport layer 103 is formed by a jet printing method, and a film thickness of the hole transport layer 103 is between 1 nm and 100 nm. The light emitting layer 104 is made of a blue luminescent polymer material. The light emitting layer 104 is formed by a jet printing method, and a film thickness of the light emitting layer 104 is between 1 nm and 100 nm. The electron transport layer 105 is made of zinc oxide. The electron transport layer 105 is formed by a jet printing method, and a film thickness of the electron transport layer 105 is between 0.5 nm and 10 nm. The cathode layer 106 is made of carbon nanotubes/(poly 3,4-ethylenedioxythiophene: polystyrene sulfonate). The cathode layer 106 is formed by a jet printing method, and a film thickness of the cathode layer 106 is between 10 nm and 1000 nm.

The poly-3,4-ethylenedioxythiophene: polystyrene sulfonate is an aqueous polymer solution, and is abbreviated as PEDOT: PSS. The poly-3,4-ethylenedioxythiophene: polystyrene sulfonate has a high conductivity. According to different formulations, the aqueous solutions with different conductivities can be obtained. The PEDOT: PSS is composed of two substances PEDOT and PSS. PEDOT is a polymer of EDOT (3,4-ethylenedioxythiophene monomer), and PSS is polystyrene sulfonate.

P-electrons of carbon atoms on the carbon nanotubes form a wide range of delocalized it -bonds. Due to significant conjugation effect, the carbon nanotubes have good conductivity. The PEDOT: PSS and the carbon nanotubes are used to form the carbon^{,} nanotube-polymer layered composite transparent electrode. The carbon nanotube-polymer layered composite transparent electrode exhibit good strength, elasticity, fatigue resistance and isotropy, thereby providing the cathode layer a good transparency and electrical conductivity.

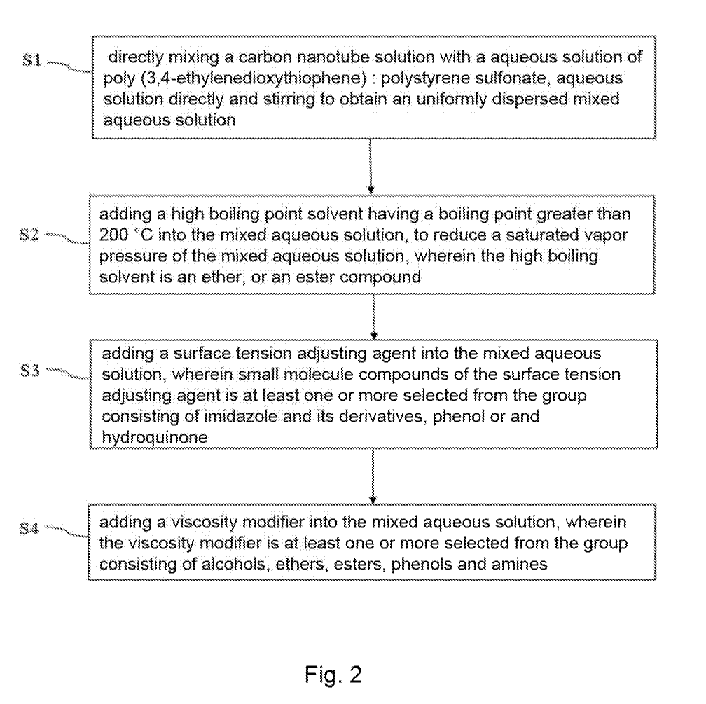

As shown in FIG. 2, this disclosure further provides a method for manufacturing a liquid material to be sprayed (i.e., a carbon nanotube-polymer composite transparent electrode (ink)) for the OLED device, which comprises:

a step S1 of directly mixing a carbon nanotube solution with a aqueous solution of poly (3,4-ethylenedioxythiophene): polystyrene sulfonate, and stirring to obtain an uniformly dispersed mixed aqueous solution;

a step S2 of adding a high boiling point solvent having a boiling point greater than 200° C. into the mixed aqueous solution, to reduce a saturated vapor pressure of the mixed aqueous solution, wherein the high boiling solvent is an ether or ester compound;

a step S3 of adding a surface tension adjusting agent into the mixed aqueous solution, wherein small molecule compounds of the surface tension adjusting agent is at least one selected from the group consisting of imidazole and its derivatives, phenol and hydroquinone; and

a step S4 of adding a viscosity modifier into the mixed aqueous solution, wherein the viscosity modifier is at least one selected from the group consisting of alcohols, ethers, esters, phenols and amines.

Moreover, before the step S1, the method further comprises a method for preparing a carbon nanotube solution. The method for preparing the carbon nanotube solution comprises:

a step S5 of dispersing the carbon nanotube powder in an aqueous solution of alkylated quatemary ammonium base, then adding a water-soluble anionic surfactant thereinto, and stirring simultaneously for obtaining the carbon nanotube solution.

The aqueous solution of alkylated quatemary ammonium base is an organic base aqueous solution of hexadecyltrimethylammonium hydroxide, dodecyltrimethylammonium hydroxide, tetradecyltrimethylammonium hydroxide, or benzyl trimethyl ammonium hydroxide; the water-soluble anionic surfactant is an acid aqueous solution of butylbenzoic, phthalic acid, cinnamic acid, phenylacetic acid, or salicylic acid.

Moreover, before the step S5, the method further comprises a method for preparing a carbon nanotube powder. The method for preparing the carbon nanotube powder comprises:

a step S6 of dispersing the carbon nanotube in an organic solvent to obtain a suspension, standing the suspension, centrifuging, washing, and then adding into a concentrated nitric acid to react at 120° C. for 4 h, followed by centrifuging, washing to be neutral, and finally drying to obtain a pure carbon nanotube powder.

The OLED device consists of pixel arrays, and each of the pixel arrays is composed of three sub-pixel wells. It is necessary to prevent the liquid material to be sprayed from overflowing to the adjacent sub-pixel wells during printing. Thus, spacer columns with low surface energy need to be arranged between the sub-pixel wells for isolation. When ink of the liquid material to be sprayed is printed into the sub-pixel wells, a volume of the various materials to be sprayed should first be made to meet requirements of the film thickness. Since a volume of the ejected droplet is determined by a diameter of a printhead, the printhead with the corresponding diameter can be selected according to a size of the sub-pixel well, and the respective film layers of the OLED device can be jet-printed.

Compared to conventional top-emitting OLED devices, a carbon nanotube-polymer composite transparent electrode was used as the cathode to enhance a conductivity of a transparent cathode in this disclosure. Besides, excellent optoelectronic properties of carbon nanotubes can achieve the requirements for the transparent cathode of the top-emitting device. Moreover, conductive polymer materials improve processability of an entire system, and makes the carbon nanotube-polymer layered composite to meet jet printing process requirements.

This disclosure has been described with preferred embodiments thereof, and it is understood that many changes and modifications to the described embodiment can be carried out without departing from the scope and the spirit of the invention that is intended to be limited only by the appended claims.

What is claimed is:

1. An organic light emitting diode (OLED) device, comprising:
a substrate;
a pixel defining layer disposed on the substrate, the pixel defining layer comprising spacer columns spaced from each other for separating two adjacent pixels;
an anode layer disposed on the substrate and located between two adjacent spacer columns;
a hole transport layer disposed on the anode layer;
a light emitting layer disposed on the hole transport layer;
an electron transport layer disposed on the light emitting layer; and
a cathode layer disposed on the electron transport layer;
wherein the cathode layer is a carbon nanotube-polymer layered composite transparent electrode, the cathode layer comprises a carbon nanotube powder and a polymer material, the carbon nanotube powder is selected from the group consisting of single-walled carbon nanotubes, double-walled carbon nanotubes, multi-walled carbon nanotubes and modified carbon nanotubes; the polymer material is an aqueous solution of poly-3,4-ethylenedioxythiophene: polystyrene sulfonate, and a solid content of the aqueous solution is 1.0% to 1.7%.

2. The OLED device according to claim 1, wherein the anode layer is made of indium tin oxide and silver, and wherein a film of the indium tin oxide is made by magnetron sputtering deposition, and a film thickness of the indium tin oxide is between 20 nm and 200 nm; and a film of the silver is made by vacuum deposition, and a thickness of the silver is between 10 nm and 100 nm.

3. The OLED device according to claim 1, wherein the hole transport layer is made of poly 3,4-ethylenedioxythiophene: polystyrene sulfonate, the hole transport layer is formed by a jet printing method, and a film thickness of the hole transport layer is between 1 nm and 100 nm.

4. The OLED device according to claim 1, wherein the light emitting layer is made of a blue luminescent polymer material, the light emitting layer is formed by a jet printing method, and a film thickness of the light emitting layer is between 1 nm and 100 nm.

5. The OLED device according to claim 1, wherein the electron transport layer is made of zinc oxide, the electron transport layer is formed by a jet printing method, and a film thickness of the electron transport layer is between 0.5 nm and 10 nm.

6. The OLED device according to claim 1, wherein the cathode layer is made of carbon nanotubes/(poly 3,4-ethylenedioxythiophene: polystyrene sulfonate), the cathode layer is formed by a jet printing method, and a film thickness of the cathode layer is between 10 nm and 1000 nm.

7. A method for manufacturing a liquid material to be sprayed for an OLED device according to claim 1, comprising:
a step S1 of directly mixing a carbon nanotube solution with a aqueous solution of poly (3,4-ethylenedioxythiophene): polystyrene sulfonate, and stirring to obtain an uniformly dispersed mixed aqueous solution;
a step S2 of adding a high boiling point solvent having a boiling point greater than 200° C. into the mixed aqueous solution, to reduce a saturated vapor pressure of the mixed aqueous solution, wherein the high boiling solvent is an ether or ester compound;
a step S3 of adding a surface tension adjusting agent into the mixed aqueous solution, wherein small molecule compounds of the surface tension adjusting agent is at least one selected from the group consisting of imidazole and its derivatives, phenol and hydroquinone; and
a step S4 of adding a viscosity modifier into the mixed aqueous solution, wherein the viscosity modifier is at least one selected from the group consisting of alcohols, ethers, esters, phenols and amines.

8. The method according to claim 7, wherein before the step S1, the method further comprises:
a step S5 of dispersing the carbon nanotube powder in an aqueous solution of alkylated quaternary ammonium base, then adding a water-soluble anionic surfactant thereinto, and stirring simultaneously, wherein the aqueous solution of alkylated quatemary ammonium base is an organic base aqueous solution of hexadecyltrimethylammonium hydroxide, dodecyltrimethylammonium hydroxide, tetradecyltrimethylammonium hydroxide, or benzyl trimethyl ammonium hydroxide; the water-soluble anionic surfactant is an acid aqueous solution of butylbenzoic, phthalic acid, cinnamic acid, phenylacetic add, or salicylic acid.

9. The method according to claim 8, wherein before the step S5, the method further comprises:
a step S6 of dispersing the carbon nanotube in an organic solvent to obtain a suspension, standing the suspension, centrifuging, washing, and then adding into a concentrated nitric acid to react at 120° C. for 4 h, followed by centrifuging, washing to be neutral, and finally drying to obtain a pure carbon nanotube powder.

10. An organic light emitting diode (OLED) device, comprising:
a substrate;
a pixel defining layer disposed on the substrate, the pixel defining layer comprising spacer columns spaced from each other for separating two adjacent pixels;
an anode layer disposed on the substrate and located between two adjacent spacer columns;
a hole transport layer disposed on the anode layer;
a light emitting layer disposed on the hole transport layer;
an electron transport layer disposed on the light emitting layer; and
a cathode layer disposed on the electron transport layer;
wherein the cathode layer is a carbon nanotube-polymer layered composite transparent electrode.

11. The method according to claim 10, wherein the anode layer is made of indium tin oxide and silver, and wherein a film of the indium tin oxide is made by magnetron sputtering deposition, and a film thickness of the indium tin oxide is between 20 nm and 200 nm; and a film of the silver is made by vacuum deposition, and a thickness of the silver is between 10 nm and 100 nm.

12. The method according to claim 10, wherein the hole transport layer is made of poly 3,4-ethylenedioxythiophene: polystyrene sulfonate, the hole transport layer is formed by a jet printing method, and a film thickness of the hole transport layer is between 1 nm and 100 nm.

13. The OLED device according to claim 1, wherein the light emitting layer is made of a blue luminescent polymer material, the light emitting layer is formed by a jet printing method, and a film thickness of the light emitting layer is between 1 nm and 100 nm.

14. The OLED device according to claim 1, wherein the electron transport layer is made of zinc oxide, the electron transport layer is formed by a jet printing method, and a film thickness of the electron transport layer is between 0.5 nm and 10 nm.

15. The OLED device according to claim 1, wherein the cathode layer is made of carbon nanotubes/(poly 3,4-ethylenedioxythiophene: polystyrene sulfonate), the cathode layer is formed by a jet printing method, and a film thickness of the cathode layer is between 10 nm and 1000 nm.
